(19) United States
(12) Patent Application Publication
(10) Pub. No.: US 2011/0083058 A1
(43) Pub. Date: Apr. 7, 2011

(54) TRAPPING SET BASED LDPC CODE DESIGN AND RELATED CIRCUITS, SYSTEMS, AND METHODS

(75) Inventors: Xinde HU, SAN DIEGO, CA (US); Shayan GARANI SRINIVASA, SAN DIEGO, CA (US); Anthony WEATHERS, SAN DIEGO, CA (US); Richard BARNDT, SAN DIEGO, CA (US)

(73) Assignee: STMICROELECTRONICS, INC., CARROLLTON, TX (US)

(21) Appl. No.: 12/889,706

(22) Filed: Sep. 24, 2010

Related U.S. Application Data
(60) Provisional application No. 61/247,923, filed on Oct. 1, 2009.

(51) Int. Cl. H03M 13/05; H03M 13/29; G06F 11/10

(52) U.S. Cl. 714/758; 714/773; 714/752; 714/763; 714/E11.032; 714/E11.034

(57) ABSTRACT

A method of generating a Tanner graph includes generating a pseudo-random parameter and selecting a subgraph within the Tanner graph to be designed, and assigning new edges to the subgraph as a function of the value of the pseudo-random parameter and as a function of prior edges, if any, that have been assigned to the subgraph. The method detects whether the subgraph contains a common feature indicative of a trapping set or sets to be avoided during generation of the Tanner graph until either the common feature is not detected or all possible combination of edges have been assigned to the subgraph. The subgraph containing no occurrences of the common feature is included as part of the Tanner graph or one of combinations is selected as the subgraph and is included as part of the Tanner graph. These operations are repeated until the entire Tanner graph is generated.

### PRIORITY CLAIM

This application claims the benefit of U.S. Provisional Patent Application No. 61/247,923, filed Oct. 1, 2009, which application is incorporated herein by reference in its entirety.

### TECHNICAL FIELD

Embodiments of the present invention relate generally to data communications and relate more specifically to systems and methods utilizing low-density parity-check (LDPC) codes to encode and decode data being communicated over a communications channel.

### BACKGROUND

Low density parity check (LDPC) codes are error correcting codes that are utilized to communicate messages or data reliably over a noisy communications channel. LDPC codes can provide very good error correction capabilities and enable the transmission of data over a communications channel at rates that approach the theoretical maximum transmission rate of the channel, which is known as the Shannon limit or Shannon capacity of the channel.

As understood by those skilled in the art, almost all LDPC codes exhibit a phenomenon known as “error floor”, meaning the slope of a curve of the sector failure rate (SFR) versus signal-to-noise ratio (SNR) decreases dramatically as the SNR increases beyond a certain level, as will now be described in more detail with reference to FIG. 1. FIG. 1 is a graph for a sample LDPC code showing the sector failure rate (SFR) versus the signal to noise ratio (SNR) for the code when being used to communicate data over a communications channel. The graph also shows the error floor phenomenon. The x-axis of the graph represents the SNR and y-axis represents the SFR. LDPC codes are block codes and in the context of magnetic disk drives are associated with blocks of data known as “sectors,” where a sector can, for example, be equal to 512 bytes of data. The sector failure rate SFR is a parameter indicating the rate that sectors being communicated contain at least one erroneous bit of data and thereby fail.

Portions of FIG. 1 where the SFR decreases approximately linearly and at a relatively steep slope are known as the “waterfall” or “cliff” portions of the curve. These are the desirable regions of the curve since, as would be expected and as is desired, increases in the SNR result in corresponding relatively steep decreases in SFR for the LDPC code. In the example graph of FIG. 1, between 11 dB and up to a SNR of approximately 12 dB the SFR drops dramatically for increases in SNR (i.e., steep slope) and corresponds to the waterfall portion of the curve. As seen in the curve, at about 12 dB the slope of the curve decreases, meaning that the SFR does not decrease as dramatically for further increases in the SNR above about 12 dB. Thus, the point 12 dB corresponds approximately to the onset of the change in slope of the curve and thus corresponds to the error floor in this example.

A typical communications channel, such as a recording channel for a magnetic disk, requires the error floor to be less than a SFR of approximately 10⁻¹². At high SNR error floor regions, the SFR is attributed to special structures contained in a parity check matrix H of the LDPC code with these special structures being known as “trapping sets,” as will be understood by those skilled in the art.

There is a need for improved LDPC codes having improved error floor characteristics that enable desired SFRs to be achieved.

### SUMMARY

Embodiments of the present invention are directed to circuits, systems, and methods of decoding data being communicated using LDPC codes having certain trapping sets eliminated or greatly reduced so that the effect of such trapping sets do not as adversely affect the error floor of communications channels utilizing the LDPC codes.

In one embodiment of the present invention a method of generating a Tanner graph for use in the decoding of data encoded with a low density parity check code includes generating a pseudo-random parameter. A subgraph within the Tanner graph to be designed is selected and new edges are assigned to the subgraph. The new edges are assigned as a function of the value of the pseudo-random parameter and as a function of prior edges, if any, that have been assigned to the subgraph. The method then detects whether the subgraph including the newly assigned edges contains a common feature indicative of a trapping set or sets to be avoided during generation of the Tanner graph. The operations of assigning new edges to the subgraph and detecting whether the subgraph including the newly assigned edges contains the common feature are repeated until either the common feature is not detected or all possible combination of edges have been assigned to the subgraph. The subgraph containing no occurrences of the common feature is included as part of the Tanner graph being generated. When the common feature is detected for all combinations of assigned edges, one of combinations is selected as the subgraph and is included as part of the Tanner graph being generated. The operations of generating a pseudo-random parameter through including the subgraph as part of the Tanner graph being generated are repeated until the entire Tanner graph is generated.

### BRIEF DESCRIPTION OF THE DRAWINGS

FIG. 1 is a graph for a sample LDPC code showing the sector failure rate (SFR) versus the signal to noise ratio (SNR) for the code and showing a phenomenon known as the error floor of the code.

FIG. 2 illustrates a sample parity check matrix for a sample (10,5) LDPC code.

FIG. 3 is a Tanner graph of the sample parity check matrix of FIG. 2.

FIG. 4 is a sample of another parity check matrix that contains a short cycle.

FIG. 5 is a Tanner graph illustrating the short cycle contained in the parity check matrix of FIG. 4.

FIG. 6 illustrates a conventional Tanner graph and an “unfolded” representation of this Tanner graph to better illustrate graphic properties of LDPC codes that can be detected utilizing such unfolded Tanner graphs.

FIG. 7 shows two unfolded Tanner graphs that provide an example of how such graphs can be utilized to graphically depict trapping sets.

FIGS. 8a-8d illustrate some of the key trapping sets that will appear in an LDPC code of column weight four if no design effort is made to avoid such trapping sets.

FIG. 9 is a subgraph illustrating a common feature contained in the trapping sets of an LPDC code of column weight four.

FIGS. 10a-10c illustrate instances of the common feature of FIG. 9 in the trapping set of FIG. 8c.

FIG. 11 is a flowchart of the process for designing the Tanner graph of an LDPC code that is trapping-set free or has a reduced number of trapping sets according to one embodiment of the present invention.

FIG. 12 is a functional block diagram of a communications channel utilizing the LDPC code designed in FIG. 11 according to another embodiment of the present invention.

FIG. 13 is a functional block diagram of a computer system including computer circuitry coupled to a data storage device that includes the communications channel of FIG. 12 according to another embodiment of the present invention.

FIG. 14 is a graph showing the improved error floor characteristics of the LDPC code including a Tanner graph formulated through the process of FIG. 11.

### DETAILED DESCRIPTION

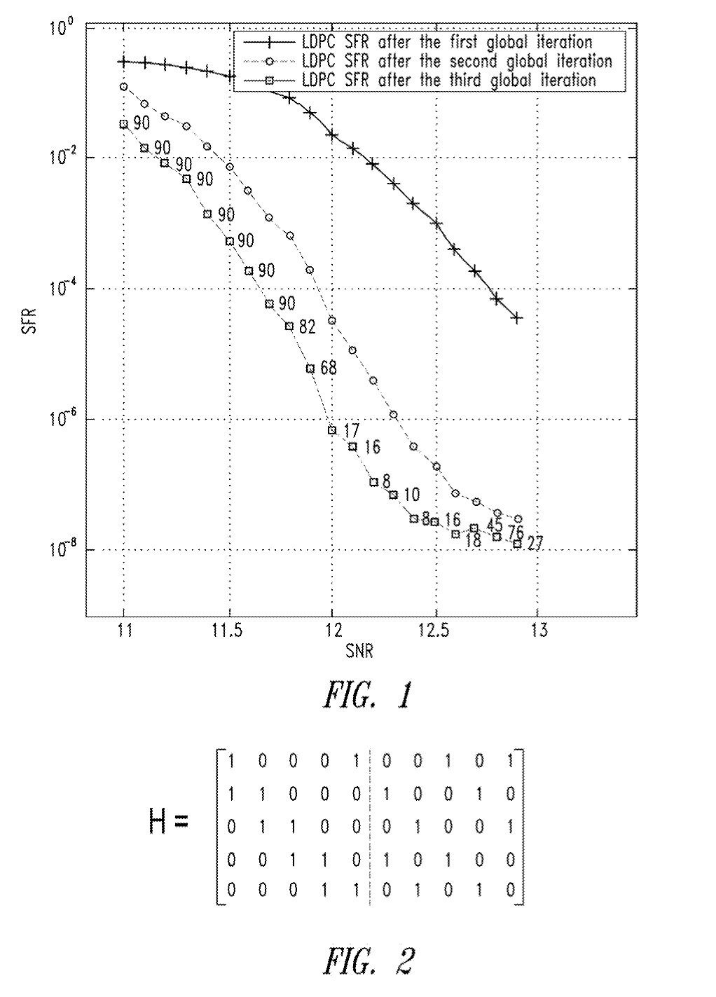

As discussed with reference to FIG. 1, the error floor of an LDPC code may make achieving a desired a sector failure rate SFR difficult or impossible. Those skilled in the art believe that special structures in the parity check matrix H of an LDPC code cause the unwanted sector failures in the error floor region of the curve. These special structures are known as “trapping sets.” While all trapping sets cannot be exhaustively enumerated, the inventors of the present application have uncovered certain common features of the trapping sets which, when eliminated from the LDPC code through the code design, significantly improve the error floor characteristics and thus the performance of the LDPC code, as will be explained in more detail below.

In the present description, certain details are set forth in conjunction with the described embodiments of the present invention to provide a sufficient understanding of the invention. One skilled in the art will appreciate, however, that the invention may be practiced without these particular details. Furthermore, one skilled in the art will appreciate that the example embodiments described below do not limit the scope of the present invention, and will also understand that various modifications, equivalents, and combinations of the disclosed embodiments and components of such embodiments are within the scope of the present invention. Embodiments including fewer than all the components of any of the respective described embodiments may also be within the scope of the present invention although not expressly described in detail below. Finally, the operation of well known components and/or processes has not been shown or described in detail below to avoid unnecessarily obscuring the present invention.

To more easily understand the present invention and embodiments thereof the concept of Tanner graphs, which are utilized to depict the parity check matrix H of LDPC codes, will first be discussed, along with the definition of various terms related thereto and different representations of the Tanner graph itself that facilitate understanding embodiments of the present invention. Referring to FIG. 2 a sample parity check matrix H is shown for a sample (n,k) LDPC code, where n=10 and represents the length of a codeword CW in the LDPC code and where k=5 and represents the number of user input, information, or message bits in the codeword. As the name “low density parity check” indicates, the parity check matrix H for an LDPC code is a long sparse matrix, where sparse means there are relatively few 1's in the matrix. The parity check matrix H representing the (n,k) LDPC code is in this example a binary ((n−k)×n) matrix. A regular LDPC code has the same number of 1's in each row (k) and in each column (j) of its parity check matrix H, whereas an irregular LDPC code does not. The parity check matrix H of FIG. 2 is a (5×10) matrix with a column weight of 2 and row weight of 4. The location of the 1's in the parity-check matrix H defines the code structure and further determines the behavior of the LDPC code during iterative decoding, as will be appreciated by those skilled in the art.

Note that the parity check matrix H of FIG. 2 is presented here only by way of example and a parity check for a real LDPC code would typically be much larger, with typical codewords CW and the corresponding parity check matrix H being much larger (e.g., typical codewords CW are thousands of bits long). As will be appreciated by those skilled in the art, HX^{T}=0 only if the vector X is a codeword CW of the LDPC code. As will be understood by those skilled in the art, data received over a communications channel is processed via a channel detector and a set of “soft decisions” or “soft information values” determined, with this set of soft information values collectively being a referred to as a received vector. The received vector is then decoded to generate the vector X where the vector X is a codeword CW and HX^{T}=0 as previously discussed above. In this way, the parity check matrix H is utilized to detect and correct errors in the vectors X, as will be discussed in more detail below.

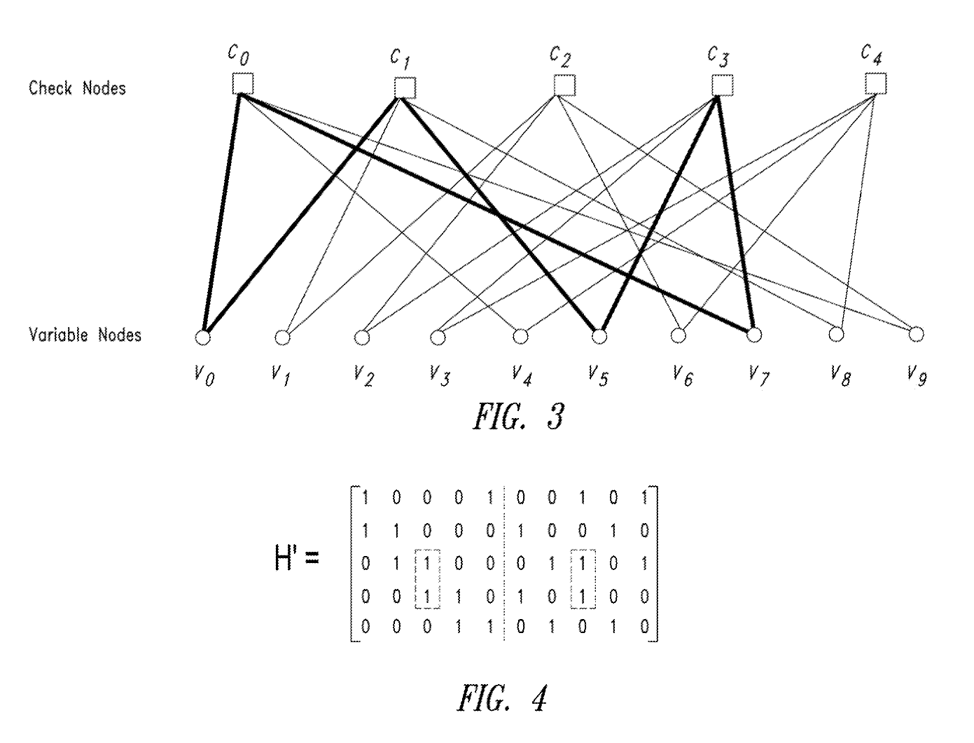

FIG. 3 is a Tanner graph of the sample parity check matrix H of FIG. 2. The Tanner graph is a bipartite graphical representation of an LDPC code (i.e., of the parity check matrix H of an LDPC code). The Tanner graph is useful for visualizing the relationship between coded bits and the parity-check constraints. A Tanner graph is a bipartite graph with bit or variable nodes Vⱼ on one side of the graph and constraint or check nodes Cₖ on the other side. Each variable node Vⱼ corresponds to a bit in a codeword CW and each check node Cₖ corresponds to one parity-check constraint on the bits in the codeword. An “edge” in the Tanner graph corresponds to a link between one bit of a codeword CW and one constraint on the bits in the codeword. An edge also corresponds to the location of a “1” in the parity check matrix H. Edges in the Tanner graph will be discussed in more detail below.

To further facilitate an understanding of aspects of the present invention and embodiments thereof, a list of terms utilized to describe various characteristics of a Tanner graph, and the relationship between a Tanner graph and a corresponding LDPC code, will now be discussed in more detail. First, as mentioned above, a check node Cₖ is defined as one parity check equation, which corresponds to one row in the parity check matrix H. A variable node Vⱼ can be viewed as an input sample of a received vector (i.e., received version of an originally transmitted codeword CW) to an LDPC decoder. Each variable node Vⱼ corresponds to one column in the parity check matrix H.

An edge in the Tanner graph of FIG. 3 is a line connecting a variable node Vⱼ and a check node Cₖ. An edge represents the fact that the parity check equation corresponding to the check node Cₖ includes the samples in the form of the corresponding variable nodes Vⱼ. For example, as seen in the parity check matrix H of FIG. 2 the first column includes 1's in the first and second rows, namely for the first and second check nodes C₀ and C₁. As a result, edges go between the variable node V₀ and the check nodes C₀ and C₁ as shown in the Tanner graph of FIG. 3. Thus, the parity check equation corresponding to check node C₀ includes the bit/sample corresponding to variable node V₀ and the same is true of the parity check equation corresponding to check node C₁, which likewise includes the sample of variable node V₀. Respective edges thus connect variable node V₀ to check nodes C₀ and C₁ as seen in the Tanner graph of FIG. 3.

Referring now to the Tanner graph of FIG. 3 and the parity check matrix H of FIG. 2, the number of ones (1's) in each column of the parity check matrix H is known as the column weight of the matrix. The column weight is also the number of edges each variable node Vⱼ is connected to and typically has a value of either three, four, or five. For example, in the sample parity check matrix H of FIG. 2 the column weight is two. Similarly, the row weight is the number of ones (1's) in each row of the parity check matrix H and is also the number of edges each check node Cₖ is connected to and has a value between ten and fifty for typical LDPC codes. The sample parity check matrix H has a row weight of four. Thus, the parity check matrix H has a column weight of two and a row weight of four and defines a regular LDPC code. The strict definition of a regular LDPC code is that its parity check matrix H has a row weight that is equal to the column weight times (n/k), namely wᵣ=w_{c}×(n/k) where wᵣ is the row weight, w_{c} is the column weight, n=10 and k=5, which is true for the parity check matrix H.

Another characteristic of the Tanner graph of FIG. 3 that must be understood is that of a “cycle.” A cycle is a set of edges that form a closed loop in the Tanner graph. One example of a cycle is illustrated by the dark lines in the Tanner graph of FIG. 3. Thus, the path from variable node V₀ to check node C₀ to variable node V₇ to check node C₃ to variable node V₅ to check node C₁ and back to variable node V₀ is an example of a cycle. The edges in a Tanner graph represent the paths through which all the information is flowing during the decoding process while cycles in a Tanner graph indicate the fact that some information may be passed back to its origin during the iterative decoding process involving use of the parity check matrix H, as will be understood by those skilled in the art and as will be discussed in more detail below.

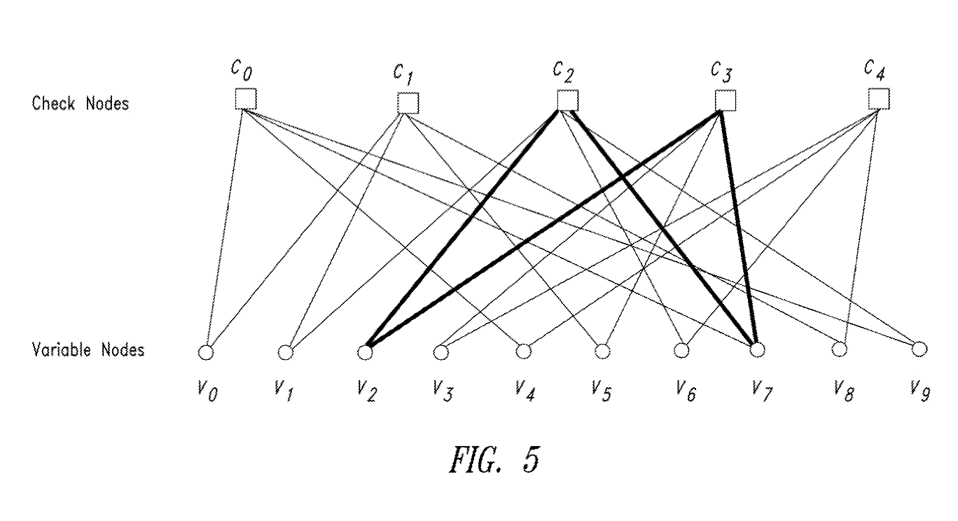

A specific type of cycle is termed a “short cycle” which, as its name implies, is a cycle that is “short” and thus traverses a path including a small number of edges in the Tanner graph. For a bipartite graph like the Tanner graph of FIG. 3 the shortest possible cycle has a length of four. As will be appreciated by those skilled in the art, short cycles should be avoided since they adversely affect the decoding performance of a corresponding LDPC code. Short cycles manifest themselves in the parity check matrix H in the form of columns of the parity check matrix having an overlap of two. By the term overlap is meant the parity check matrix H contains 1's in a given column of the parity check matrix for adjacent rows in the matrix. An overlap of two thus means such 1's occur twice for adjacent rows of the parity check matrix H. The parity check matrix of FIG. 2 contains no such short cycles while another parity check matrix H′ of FIG. 4 containing a short cycle is shown to better illustrate this concept. The parity check matrix H′ contains a short cycle due to the two overlaps in the third column (V₂) and the eighth column (V₇) of the third row (C₂) and fourth row (C₃). In FIG. 4 the two overlaps are indicated through the dotted line boxes surrounding the corresponding 1's in both instances. FIG. 5 is a Tanner graph illustrating the short cycle contained in the parity check matrix H′ of FIG. 4. As seen in the Tanner graph of FIG. 5 the short cycle contains four edges and corresponds to the path from variable node V₂ to check node C₂ to variable node V₇ to check node C₃ and back to variable node V₂.

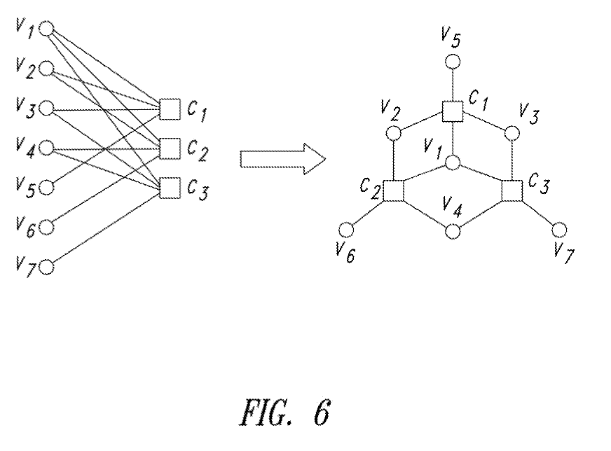

To better illustrate graphic properties LDPC codes the conventional Tanner graph can be “unfolded” to form an equivalent two dimensional graph as shown in FIG. 6. FIG. 6 illustrates a conventional Tanner graph on the left and an “unfolded” representation of this Tanner graph on the right. Such an unfolded Tanner graph will be utilized to better illustrate salient graphic properties of LDPC codes that are utilized in embodiments of the present invention, as will be described in more detail below.

As mentioned above, the sample parity check matrix H and Tanner graph of FIG. 3 are merely for the purpose of illustrating the concepts being discussed. The same is true of the matrix of H′ and Tanner graphs of FIGS. 5 and 6. These matrices and graphs are much smaller than they would be for real LDPC codes, which typically contain at least 1000 variable nodes Vⱼ (i.e., codewords CW at least 1000 bits long). As a result of the sheer size of a real parity check matrix H, and the associated Tanner graph, it is extremely difficult to meaningfully outline the complete structure of an entire LDPC code. Instead, in practice smaller portions of the parity check matrix H and the Tanner graphs associated with these smaller portions are studied and used characterize the LDPC code.

The following concepts and terms relating to these smaller portions of the parity check matrix H and the Tanner graphs associated with these smaller portions are now defined. First, the Tanner graph of a smaller portion of parity check matrix H is defined as a subgraph. A subgraph is thus a Tanner graph representing a subset of the parity check matrix H and thus a subset of the LDPC code. In a typical subgraph some edges connected to check nodes Cₖ are omitted while all edges connected to the included variable nodes Vⱼ are shown.

Within a subgraph, a neighbor is defined as the set of all check nodes Cₖ that a certain variable node Vⱼ or group of variable nodes is or are connected to. For example, in the unfolded Tanner graph on the right side of FIG. 6 the check nodes C₁, C₂, and C₃ are neighbors of variable node V₁ while check nodes check nodes C₂ and C₃ are neighbors of variable node V₄. An even-neighbor is defined as a neighbor that has an even number of edges connected to associated variable nodes in the subgraph. In the unfolded Tanner graph each of the check nodes C₁, C₂, and C₃ is an even neighbor since each check node is connected through four edges to associated variable nodes Vⱼ. Conversely, an odd-neighbor is defined as a neighbor that has an odd number of edges connected to associated variable nodes in the subgraph. None of the check nodes C₁, C₂, and C₃ in the unfolded Tanner graph of FIG. 6 is an odd-neighbor. If the variable node V₇ was eliminated, for example, then the check node C₃ would be an odd-neighbor as being connected through respective edges to variable nodes V₁, V₃, and V₄.

The next concept to be considered for a subgraph is that of a trapping set. A trapping set is a set of variable nodes Vⱼ that cannot always be decoded to the correct value after any given number of iterations during the iterative decoding process of codewords CW forming the LDPC code. Trapping sets are usually caused by a cluster of interconnected variable nodes Vⱼ that are not “well-connected” to the rest of the check nodes Cₖ and cause a failure in decoding, as will be understood by those skilled in the art. As a result of trapping sets, during the decoding process it is possible to get “stuck” in a trapping set instead of converging to the correct solution. In this way trapping sets cause the decoding process to fail, which leads to unwanted retransmission of the sectors and effectively lowers the throughput of the communications channel due to the erroneous sectors.

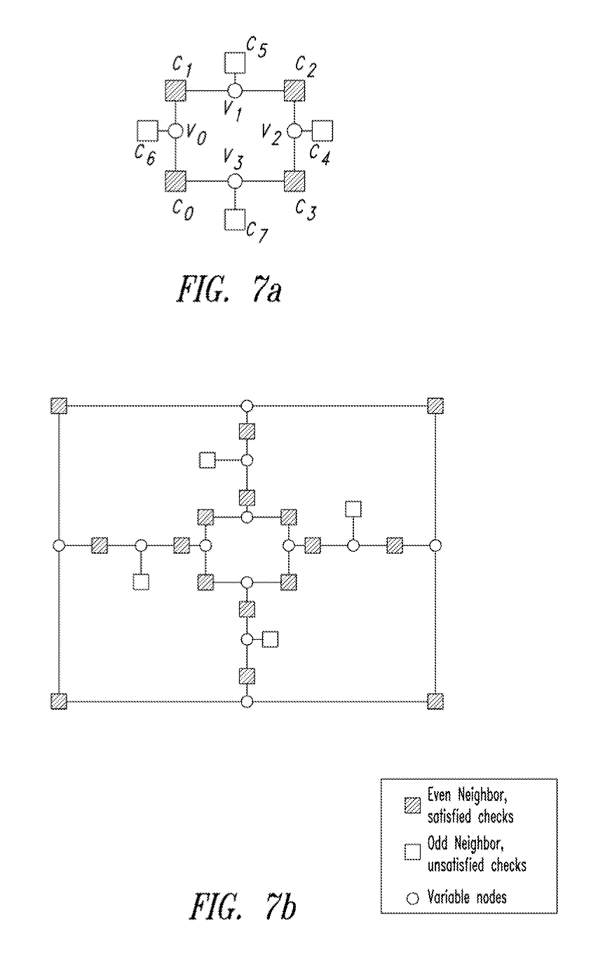

A trapping set can be defined either by the decoding process or by a graphic feature of a subgraph. More specifically, trapping sets are a set of erroneous bit structures within a Tanner graph (parity check matrix H) that do not change their decisions over multiple iterations during the iterative decoding process. These structures are so named because the decoder thereby effectively becomes “trapped” in an erroneous state and is unable to recover from it, as will be appreciated by those skilled in the art. If defined by the decoding process, for each sector failure in the error floor region (see discussion above relating to FIG. 1) the remaining erroneous bits after a large number of iterations (e.g., greater than 100 iteration) correspond to a trapping set. If defined by graphic features of a subgraph, a trapping set can be defined by the combination of odd and even neighbors in the subgraph, as will be described in more detail below. For example, over ninety-nine percent of the sector failures in the error floor region of a column-weight three Margulis code (2640, 1320) are caused by one of the two trapping sets shown in the unfolded Tanner graphs depicted in FIG. 7. Thus, the presence of one or both of these trapping sets causes the vast majority of sector in the error floor region for this Margulis code.

In the unfolded Tanner graphs of FIG. 7 the circles represent variable nodes Vⱼ and the squares represent check nodes Cₖ. This was also true in the unfolded Tanner graph of FIG. 6. In the representation in FIG. 7, however, the check nodes Cₖ are further color coded to indicate whether each check node is an even- or odd-neighbor. If a check node Cₖ is an even-neighbor the associated square in the unfolded Tanner graph is gray-shaded. Conversely, if a check node Cₖ is an odd-neighbor the associated square is not shaded. So in the unfolded Tanner graph on the left of FIG. 7, there are four variable nodes V₀-V₃, four even-neighbor check nodes C₀-C₃, and four odd-neighbor check nodes C₄-C₇. FIG. 7 illustrates how such subgraphs can be used to graphically illustrate trapping sets contained in a Tanner graph for an error correcting codes. The graphs of FIG. 7 are for a Margulis code as previously mentioned but the concepts apply to LDPC codes as well.

Turning now to the specific application of such subgraphs to LDPC codes, typical trapping sets for column weight w_{c} of three or four LDPC codes (i.e., w_{c} equals either 3 or 4) will now be discussed in more detail. LDPC codes having a column weight w_{c} are typically utilized in order to balance the performance of the code in the waterfall region and while also reducing the error floor of the code. Recall, as previously discussed with reference to FIG. 1 the portions of this curve where the sector failure rate SFR decreases approximately linearly and at a relatively steep slope are known as the waterfall portions of the curve and the onset of the change in slope of the curve corresponds to the error floor. Column weight w_{c} three or four LDPC codes thus provide reasonably good performance in the waterfall portion (i.e., relatively steep slope so increases in signal-to-noise ratio SNR dramatically reduce sector failure rate SFR) while reducing the error floor (i.e., pushes out or increases the value of the signal-to-noise ratio SNR associated with the error floor).

Due to these desirable characteristics of LDPC codes having column weight w_{c} three or four the following embodiments of the present invention will utilize such codes by way of example. Typical trapping sets for this type of LDPC code will now be discussed in detail, and graphic features of these trapping sets identified. Recall, a trapping set was defined as a set of variable nodes Vⱼ that cannot always be decoded to the correct value after any given number of iterations during the iterative decoding process of codewords CW forming the LDPC code. For the described embodiments, a trapping set is more specifically defined as a subgraph within the Tanner graph of the LDPC code having a number of even-neighbors that is equal or greater than the number of odd-neighbors in the subgraph. Low weight trapping sets, meaning the trapping set contains a small number of variable nodes Vⱼ, are believed to be the most damaging types of trapping sets adversely affecting performance of the LDPC code. Thus these low weight trapping sets are the focus of the described embodiments of the present invention.

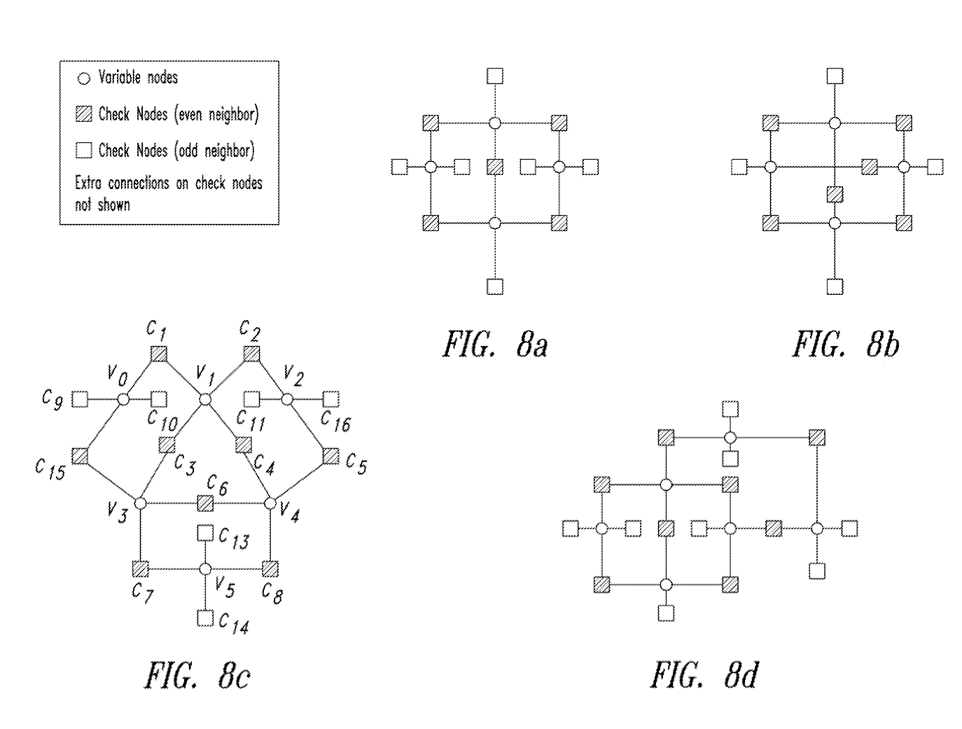

Focusing on low weight trapping sets allows various types of types of trapping sets to be enumerated for certain parameters of a given LDPC code. For example, for a column weight w_{c}=4 LDPC code FIGS. 8a-8d illustrate some of the key trapping sets that will appear in an LDPC code if no design effort is made to avoid such trapping sets. The goal of the trapping-set based LDPC code design approach being described is to minimize the number of trapping sets contained in the parity check matrix H of an LDPC code. Note that although it is possible to list all the typical structures of trapping sets for certain LDPC codes it is nearly impossible to examine whether a given LDPC code contains these trapping sets. According to one embodiment of the present invention, common features of these trapping sets are examined instead of the whole list of all trapping sets, greatly simplifying the detection and elimination of trapping sets. If the existence of features common to all trapping sets, termed “common features” herein, are eliminated then the LDPC code will be free of trapping sets. The term “common features” thus corresponds to a set of variable nodes Vⱼ and the associated check nodes Cₖ that are contained in all of the trapping sets for the LDPC code of column weight w_{c} equal to four.

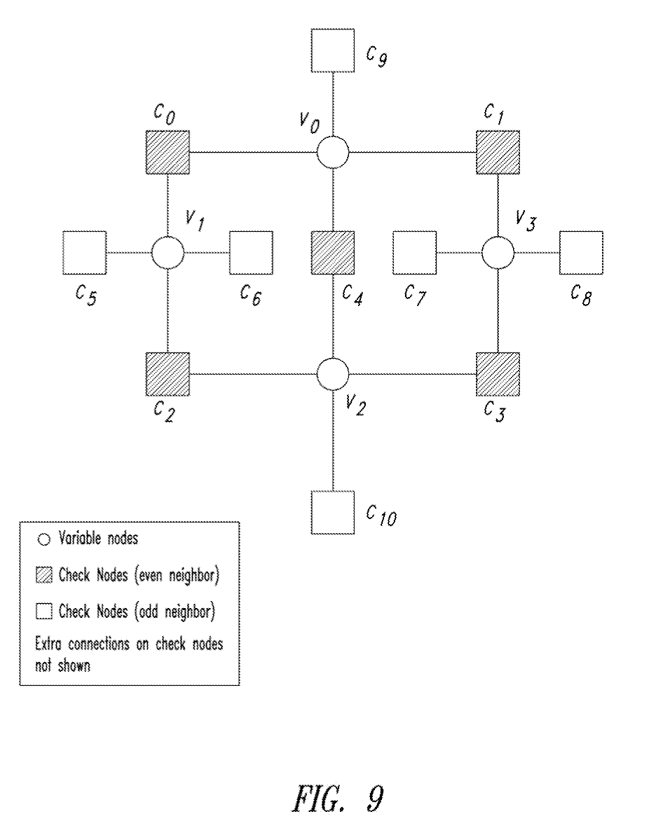

FIG. 9 is a subgraph illustrating a common feature contained in the trapping sets of an LPDC code of column weight w_{c} equal to four. Accordingly, eliminating the common feature from the parity check matrix H of this LDPC code eliminates or greatly reduces the number of trapping sets contained in the LDPC code. The common feature of FIG. 9 can be characterized as two six-cycles sharing a variable-check-variable node link, which is also known as a two-edge connectivity of six-cycles, as will be appreciated by those skilled in the art. The two-six-cycles correspond to a first “six-cycle” from check node C₁ to variable node V₀ to check node C₄ to variable node V₂ to check node C₃ to variable node V₃ and back to check node C₁ (C₁>>V₀>>C₄>>V₂>>C₃>>V₃). A second “six-cycle” is from check node C₀ to variable node V₀ to check node C₄ to variable node V₂ to check node C₂ to variable node V₁ and back to check node C₀ (C₀>>V₀>>C₄>>V₂>>C₂>>V₁). The “variable-check-variable node link” correspond to variable node V₀, check node C₄, and variable node V₂ (V₀>>C₄>>V₂). One or more of the common feature of FIG. 9 is found in all the trapping sets for an LDPC code of column weight w_{c} equal to four. Note that the common feature of FIG. 9 is the same as the trapping set shown in FIG. 8a.

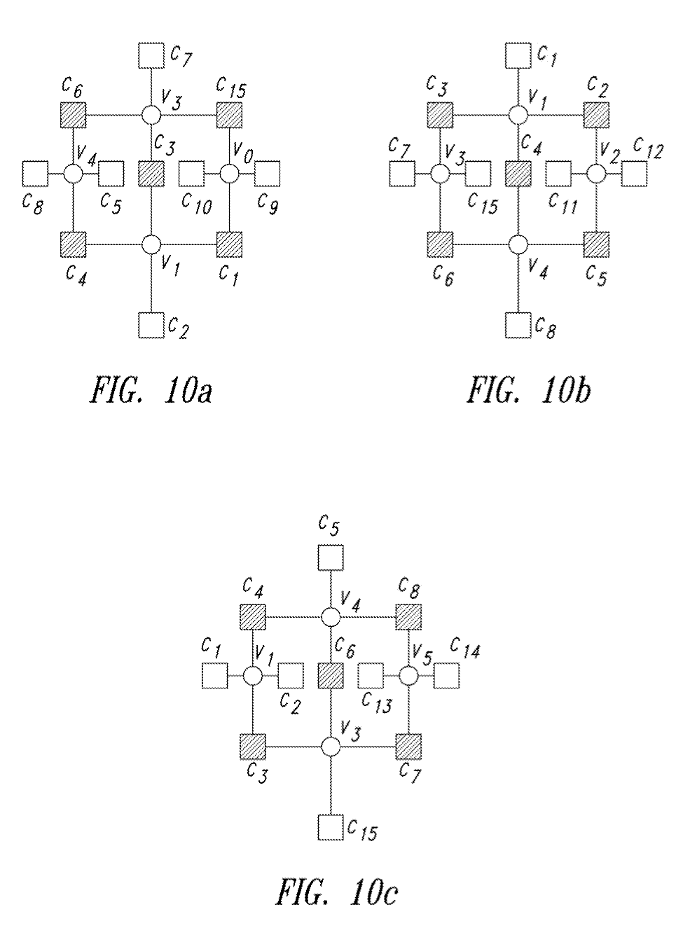

Referring to FIG. 8c, three instances of the common feature of FIG. 9 occur in the trapping set of FIG. 8c. A first instance corresponds to the nodes of FIG. 8c as redrawn in FIG. 10a. Second and third instances of the common feature of FIG. 9 in FIG. 8c as shown respectively in FIGS. 10b and 10c. FIGS. 10a-10c are shown merely to demonstrate that the common feature of FIG. 9 is indeed contained in each of the trapping sets of the LDPC code as shown in FIGS. 8a-8c. Note that in FIGS. 10a-10c some of the check nodes Cₖ are indicated having changed from even-neighbor to odd-neighbor, or vice versa. This is permissible because, as mentioned above, when drawing subgraphs additional connections or edges to check nodes are omitted.

By eliminating the common feature in the parity check matrix H during the design process of the LDPC code, the LDPC code is trapping-set free. Moreover, if the number of instances of this common feature are merely reduced but not eliminated then the LDPC code will nonetheless contain fewer trapping sets, thereby still improving the error floor performance of the code.

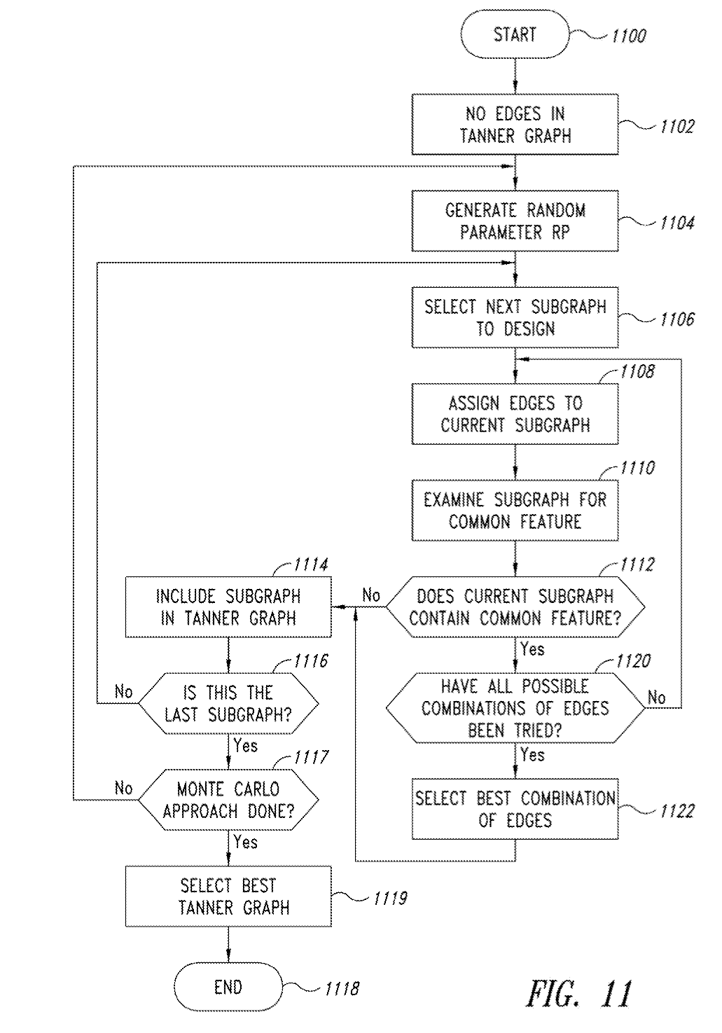

The design process for forming the Tanner graph of an LDPC code that is a trapping-set free or has a reduced number of trapping sets is shown in more detail in the flowchart of FIG. 11. For given parameters of the LDPC code (length of codewords CW, code rate, etc.) the size of the parity check matrix H and thereby the numbers of variable nodes Vⱼ and check nodes Cₖ are set. The code design process illustrated in the flowchart of FIG. 11 is the process of assigning edges to the Tanner graph for the LDPC code. Recall, assigning edges in the Tanner graph corresponds to assigning the “1”s in the parity check matrix H since a “1” in the parity check matrix leads to an edge in the Tanner graph. The process of FIG. 11 can be described as a progressive approach in that edges in the Tanner graph are assigned “progressively,” one edge or one group of edges at a time.

This progressive process begins in step 1100 and proceeds immediately to step 1102 in which the a blank Tanner graph is effectively created, meaning the Tanner graph has no edges, only the predetermined numbers of variable nodes Vⱼ and check nodes Cₖ determined by the characteristics of the LDPC code being designed. The process then goes to step 1104 and a pseudo-random parameter RP is generated. This parameter RP determines a new set of edges for a portion of the Tanner graph being designed at this point in time. The “portion” of the Tanner graph being designed corresponds to a subgraph of the Tanner graph. Thus, the Tanner graph is designed one subgraph at a time according to this process. Due to the parallelism required when decoding the LDPC code, if one edge is set then one group of edges is set.

After the parameter RP is generated, the process goes to step 1106 and the next subgraph to be designed in the Tanner graph is selected. The first time through the process a first subgraph is selected. As previously discussed, a subgraph is a Tanner graph representing a subset of the parity check matrix H and thus a subset of the LDPC code being designed. Thus, although step 1106 is described as selecting the next “subgraph” to be designed, the process is actually selecting a group or set of variable nodes Vⱼ and check nodes Cₖ which, when edges are added or assigned to these nodes, forms a subgraph. The step 1106 is described a selecting the next “subgraph” merely to simplify the present description.

The process then goes to step 1108 and, based upon the parameter RP, assigns edges to the presently selected subgraph being designed, thereby effectively forming the subgraph. From step 1108 the process proceeds to step 1110 and examines this newly formed subgraph to determine whether the subgraph contains the common feature (see FIG. 9). Recall, this common feature is a structure present in all trapping sets for the LDPC code being designed and thus, if present, indicates that the present subgraph contains at least one trapping set.

The process then goes to step 1112 and determines whether this examination of step 1110 indicates the present subgraph includes the common feature. If this determination is negative this indicates the present subgraph contains no occurrences of the common feature and thus no trapping sets, meaning that the subgraph has the ideal characteristics for being included in the Tanner graph. Accordingly, in this situation the process proceeds to step 1114 and the present subgraph containing no trapping sets is included in the Tanner graph. From step 1114 the process then goes to step 1116 and determines whether the current subgraphs just included in the Tanner graph in step 1114 is the last subgraphs required to completely form the Tanner graph. If this determination is true the process then proceeds to step 1118 and ends. If the determination in step 1116 is not true, this indicates more subgraphs remain to be designed and the process goes back to step 1106 and selects the next subgraph to be designed.

When the determination and step 1112 is positive, the present subgraph being designed contains a common feature and thus includes at least one trapping set. In this situation, the process goes from step 1112 to step 1120 and determines whether all possible combinations of edges have been tried for the present subgraph. When the determination in step 1120 is negative, indicating all possible combinations of edges for the subgraph have not yet been tried, the process goes back to step 1108 and newly assigns to the subgraph. The process continues executing a loop consisting of steps 1108, 1110, 1112, and 1120 until either: 1) the determination in step 1112 indicates a common feature is not present in the subgraph with the most recently assigned edges; or 2) the determination in step 1120 is positive thereby indicating that all possible combinations of edges for the current subgraph have been tried.

At this point, when all possible combinations of edges for the current subgraph have been tried such that the determination in step 1120 is positive, the process proceeds to step 1122 and the best combination of edges for the subgraph presently being designed is selected. The determination in step 1120 would typically be made by selecting the combination of edges for the subgraph that resulted in the fewest number of occurrences of the common feature. Once the best combination of edges is selected in step 1122 the process returns to step 1114 and the subgraph with the selected combination of edges is included in the Tanner graph. The process continues executing the steps 1106-1116, 1120, and 1122 until the determination in step 1116 is positive, indicating that the design of the present Tanner graph for the LDPC code is complete.

From step 1116 the process then goes to step 1117 and determines whether a Monte Carlo approach has been completed or whether another Tanner graph should be generated pursuant to this Monte Carlo approach. According to this Monte Carlo approach the overall process is repeated multiple times for different pseudo-random parameters RP generated in step 1104. Accordingly, when step 1117 determines the Monte Carlo approach is not yet complete the process then goes back to step 1104 and a new random parameter RP selected, and thereafter the above steps are repeated until the process once again returns to step 1117, meaning that another Tanner graph using the newly generated random parameter has been created.

Once a desired number of Tanner graphs have been created the determination in step 1117 is positive and the process proceeds to step 1119 and the “best” resulting Tanner graph selected from among the multiple Tanner graphs that have been generated. Once again, the “best” Tanner graph would be the Tanner graph containing the smallest number of trapping sets. Where multiple Tanner graphs contain the same number of trapping sets other criteria, such as minimization of six cycle or eight cycle subgraphs, could be utilized to select the final Tanner graph to be used for the LDPC code. Once the best Tanner graph is selected in step 1119, the process goes to step 1118 and terminates.

LDPC codes can be regular or irregular and/or structured. Regular implies uniform column weight for all the variable nodes and irregular implies non-uniform column weight distribution. Whether they are irregular/regular, LDPC codes can be from a class of structured codes like quasi-cyclic, difference set based etc. Structure in graphs ensures ease of hardware implementation. For example, in regular geometries such as quasi-cyclic case, the random parameter RP will be a number that is modulo(p) where “p” is parallelism. During this step, we have to make sure that new links added do not have any short cycles, i.e., 4 cycles in the graph. There is a one-to-one correspondence between the random parameter RP (where RP is mod (p)) selected and the choice of the subgraph that is selected.

In step 1108, new edges are basically dictated by the structure of the LDPC code and the parameter RP which says how the variable nodes Vⱼ are to be connected to check nodes Cₖ to avoid short cycles. In a first pass, all variable nodes Vⱼ can be connected to check nodes Cₖ such that the column weight w_{c} of the variable node is one. Subsequently additional edges are added to increase the column weight w_{c} of the variable nodes Vⱼ while ensuring that there are no short cycles of length four due to additional edges being added, trapping sets as defined by the common feature of FIG. 9 are avoided as best possible, and two edge connectivity between nested six cycle or higher subgraphs are avoided.

The code design process illustrated in the flowchart of FIG. 11 is dependent upon parameters of the LDPC code being designed, such as code rate, code structure (usually designed to fit the hardware structure of the decoder), and column weight. Even with all the key trapping sets enumerated, designing an LDPC code that is devoid of all trapping sets at a code rate of 0.85˜0.91 is unrealistic. As will be understood by those skilled in the art, the code rate is defined as (k/n) where, as previously discussed, n is the length of a codeword CW in the LDPC code and k is the number of user input, information, or message bits in the codeword. The goal of the LDPC code design through the process of FIG. 11 is to minimize the number of occurrences of the common feature of FIG. 9 and in this way improve the performance of the code.

An example of an LDPC code for which a Tanner graph can be designed according to embodiments of the present invention is a quasi-cyclic code LDPC code. Such a quasi-cyclic LDPC code has a parity check matrix H, and thus a Tanner graph, that is formed by sub-matrices consisting of circulant matrices. These circulant matrices in the parity-check matrix H are cyclically shifted identity matrices. For such quasi-cyclic codes, the pseudo-random parameter RP generated in step 1104 of FIG. 11 is a number that is modulo (p) where p is the parallelism of the code.

In quasi-cyclic LDPC codes, the parity check matrix H is formed as follows. There are three parameters that define the characteristics of the parity check matrix H, namely row weight wᵣ, column weight w_{c}, and parallelism p. For example, if row weight wᵣ=3, column weight w_{c}=2, and parallelism p=4 then a parity check matrix H of size (wᵣ×w_{c}) is populated with entries that are modulo(p) or modulo 4 in this example. Thus, for example, the parity check matrix could be as follows:

$$H = [ \begin{matrix}{a}^{( 0 )} & {a}^{( 0 )} & {a}^{( 0 )} \\ {a}^{( 1 )} & {a}^{( 2 )} & {a}^{( 3 )}\end{matrix} ]$$

The a⁽⁰⁾ in the parity check matrix H is an identity matrix I of size 4×4, namely:

$${a}^{( 0 )} = [ \begin{matrix}1000 \\ 0100 \\ 0010 \\ 0001\end{matrix} ]$$

The matrix a⁽¹⁾ is the identity matrix I shifted by one unit circularly to the right:

$${a}^{( 1 )} = [ \begin{matrix}0100 \\ 0010 \\ 0001 \\ 1000\end{matrix} ]$$

Similarly, the matrix a⁽²⁾ is the identity matrix I shifted by two units circularly to the right and the matrix a⁽³⁾ is the identity matrix I shifted by three units circularly to the right.

The overall parity check matrix H is thus as follows:

$$H = [ \begin{matrix}100010001000 \\ 010001000100 \\ 001000100010 \\ 000100010001 \\ 010000100001 \\ 001000011000 \\ 000110000100 \\ 100001000010\end{matrix} ]$$

The random parameter RP in step 1104 of FIG. 11 would thus in this example correspond to choosing the values of the sub-matrices a⁽⁰⁾, a⁽¹⁾, a⁽²⁾, a⁽³⁾. Once the values of the sub-matrices a⁽⁰⁾, a⁽¹⁾, a⁽²⁾, a⁽³⁾ are selected, the process then proceeds with steps 1106 et seq. to examine the corresponding subgraphs for the common feature of FIG. 9 and to avoid short cycle of length four and minimize cycles greater than a length of six. This example quasi-cyclic code has been provided merely to demonstrate an example of the pseudo-random parameter RP of step 1104 and how the value of this parameter would then be utilized to assign edges in a subgraph based upon the value of the pseudo-random parameter.

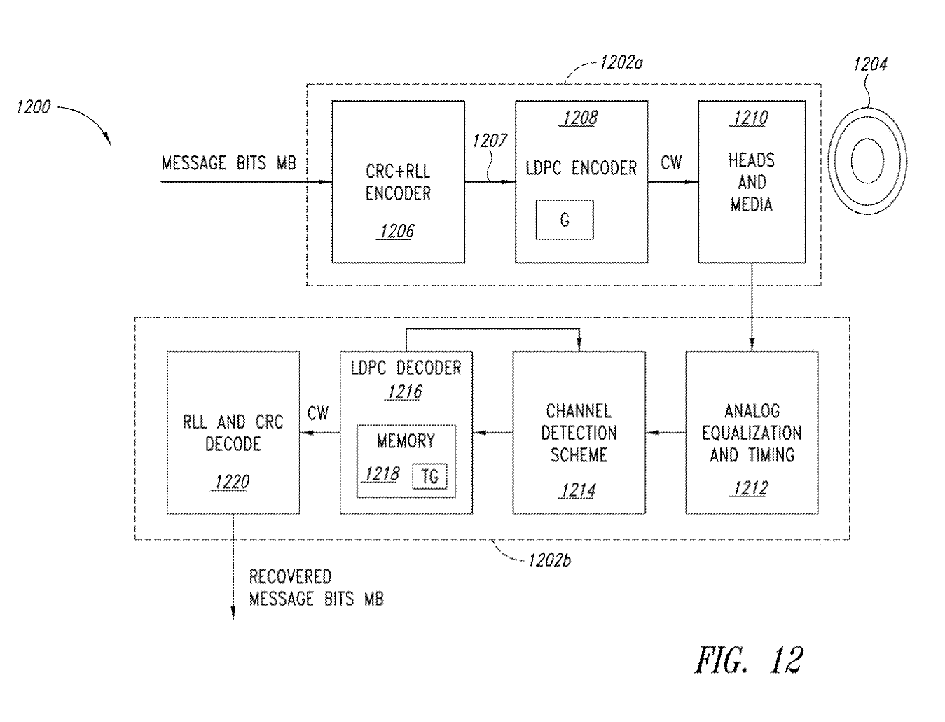

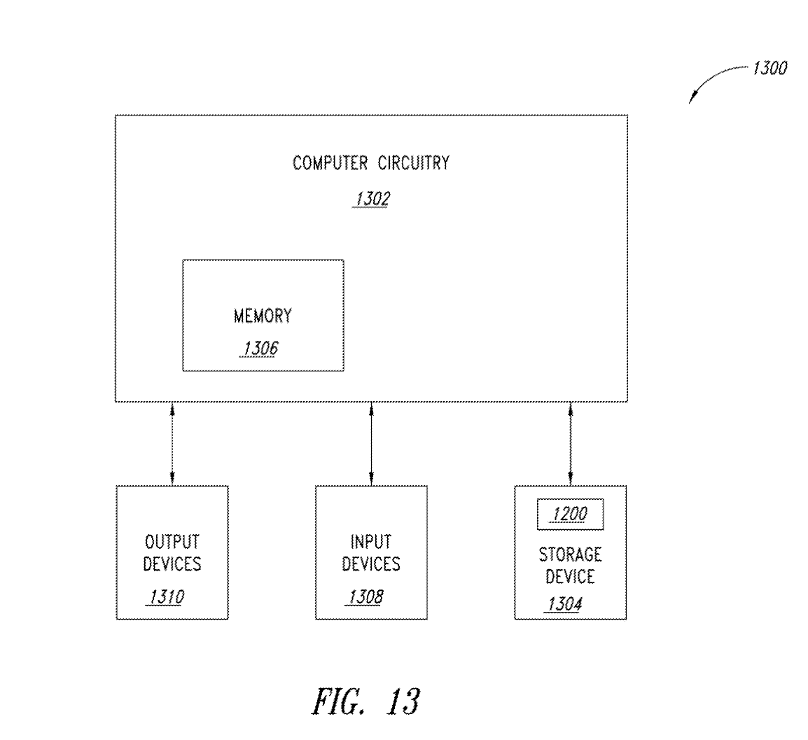

FIG. 12 is a functional block diagram of a communications channel 1200 utilizing the LDPC code designed in FIG. 11 according to another embodiment of the present invention. The communications channel 1200 includes a write portion 1202a that encodes received message bits MB utilizing the LDPC code designed via the process of FIG. 11 and stores these encoded message bits on a storage medium 1204, such as a magnetic or optical disk or other suitable type of memory device. A read portion 1202b reads the encoded data from the storage medium 1204 and decodes this encoded data to thereby output the originally stored message bits MB from the communications channel 1200.

There are k message bits MB that are input to the write portion 1202a. More specifically, in the write portion 1202a a cyclic redundancy check (CRC) and run length limited (RLL) encoder 1206 receives the k message bits MB. First, the encoder 1206 applies a CRC code to the k message bits to generate CRC coded data from the message bits. CRC coded data is generated for each k-bit block of message bits MB. The encoder 1206 then performs RLL encoding on the CRC coded data to thereby generate RLL coded data 1207. The RLL encoding helps with timing requirements for accurately reading data from the storage medium 1204, as will be appreciated by those skilled in the art.

The encoder 1206 provides the RLL coded data 1207 to an LDPC encoder 1208 that includes a generator matrix G for encoding the CRC and RLL encoded data to generate codewords CW of the LDPC code. An LDPC code includes the generator matrix G for encoding data into corresponding codewords CW and a parity check matrix H and corresponding Tanner graph for decoding the codewords as discussed in detail above. The LDPC encoder 1208 provides the generated codewords CW to heads and media circuitry 1210, which then stores these codewords on the storage medium 1204.

During a read operation, the read portion 1202b reads data stored on the storage medium 1204 and processes the data to output the originally stored message bits MB. More specifically, the read portion 1202b includes analog equalization and timing circuitry 1212 that works in combination with the heads and media circuitry 1210 to sense data stored on the storage medium 1204. The detailed operation of the analog equalization and timing circuitry 1212, heads and media circuitry 1210, and other components in a communication channel 1200 will be understood by those skilled in the art and thus are not described in more detail herein in order to avoid unnecessarily obscuring aspects of the present invention. Briefly, the equalization and timing circuitry 1212 equalizes analog signals from the heads and media circuitry 1210 that are generated in sensing data stored on the storage medium 1204. This equalization compensates for intersymbol interference in the signal from the heads and media circuitry 1210 that corresponds to the data being sensed from the storage medium 1204. The analog equalization and timing circuitry 1212 also performs analog-to-digital conversion of the equalized signal and outputs equalized samples that are digital signals corresponding to the data being read.

Channel detection scheme circuitry 1214 receives the equalized samples from the analog equalization and timing circuitry 1212. The channel detection scheme circuitry 1214 performs the iterative decoding of the equalized samples using an associated iterative decoding algorithm, typically the soft output Viterbi algorithm (SOVA) or the BCJR algorithm, as will be appreciated by those skilled in the art. The channel detection scheme circuitry 1214 outputs soft decisions or soft information values, namely log-likelihood ratios of the detected bits to the LDPC decoder 1216. The LDPC decoder 1216 includes a memory 1218 such as a FLASH or read only memory that stores the Tanner graph TG generated for the LDPC code according to embodiments of the present invention, such as the Tanner graph generated through the process of FIG. 11. There is feedback between the channel detection scheme circuitry 1214 and the LDPC decoder 1216 using standard turbo-equalization techniques, as will be understood by those skilled in the art. The LDPC decoder 1216 then outputs codewords CW to RLL and CRC decode circuitry 1220 which operates to decode the previous RLL encoding and utilizes the CRC codes to determine the accuracy of the data being read. Once the RLL and CRC decode circuitry 1220 have decoded the codewords CW the circuitry outputs the message bits MB originally input to the communications channel 1200.

Although the heads and media circuitry 1210 is shown as being contained in the write portion 1202a, this circuitry can be viewed as belonging to both the write portion and read portion 1202b since the circuitry functions to access data stored on the storage medium 1204 during both read and write operations of the communications channel 1200. Also it should be noted that the storage medium 1204 can include different types of storage media in different embodiments of the present invention, such as magnetic disks, optical disks, FLASH memory, and so on.

FIG. 13 is a functional block diagram of an electronic system 1300 such as a computer system including electronic circuitry 1302 such as computer circuitry coupled to a data storage device 1304 that includes the communications channel 1200 of FIG. 12. Typically, the computer circuitry 1302 also includes memory 1306, typically random access memory (RAM), for storing data and programming instructions when executing software for performing various computing functions, such as software like word processors or spreadsheets to perform specific calculations or tasks. When executing software the computer circuitry 1302 also accesses data stored in the data storage device 1304 through the communications channel 1200. The data storage device 1304 may be a hard or floppy magnetic disk, tape cassette, compact disk read-only (CD-ROM) and compact disk read-write (CD-RW) memory, digital video disk (DVD), FLASH memory, or other suitable storage device. The computer system 1300 further includes one or more input devices 1308, such as a keyboard or a mouse, coupled to the computer circuitry 1302 to allow an operator to interface with the computer system. Typically, the computer system 1300 also includes one or more output devices 1310 coupled to the computer circuitry 1302, such as a printer, a video display, sound system, and so on.

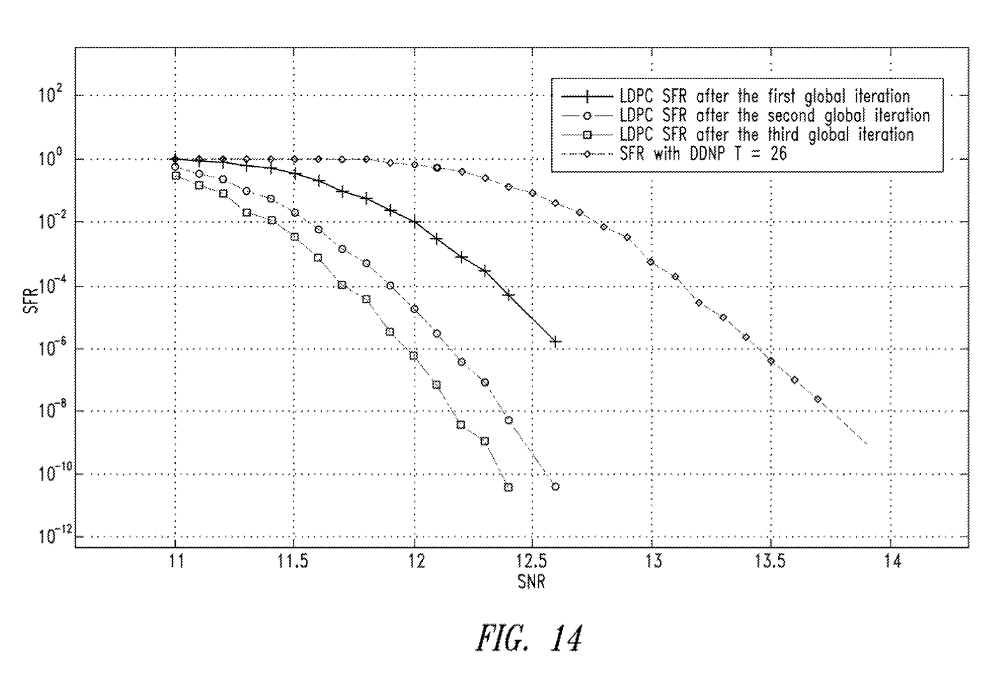

FIG. 14 is a graph showing the improved error floor characteristics of the LDPC code including a Tanner graph formulated through the process of FIG. 11. Refer back to FIG. 1 and the associated description thereof for more details regarding such graphs, commonly referred to as waterfall diagrams. As seen in FIG. 14, no error floor is seen for SNRs beyond 12.5 dB, in contrast to the diagram of FIG. 1. Accordingly, note the significantly lower SFRs (less than 10⁻¹⁰ at around 12.5 dB in FIG. 12) when compared to the diagram of FIG. 1 (not even 10⁻⁸ at around 12.5 dB). FIG. 14 accordingly shows significant improvement in the error floor performance for LDPC codes having Tanner graphs generated through the process of FIG. 11.

One skilled in the art will understand that even though various embodiments and advantages of the present invention have been set forth in the foregoing description, the above disclosure is illustrative only, and changes may be made in detail, and yet remain within the broad principles of the invention. For example, if damaging types of trapping sets other than low weight trapping sets of FIGS. 8a-8c are identified, the concepts relating to the described embodiments can be applied to such trapping sets as well. Furthermore, components described above with reference to FIGS. 12 and 13 may be implemented using either digital or analog circuitry, or a combination of both, and also, where appropriate, may be realized through software executing on suitable processing circuitry. Therefore, the present invention is to be limited only by the appended claims.

What is claimed is:

1. A method of generating a Tanner graph for use in the decoding of data encoded with a low density parity check code, the method comprising:
generating a pseudo-random parameter;
selecting a subgraph within the Tanner graph to be designed;
assigning new edges to the subgraph, the new edges being assigned as a function of the value of the pseudo-random parameter and as a function of prior edges, if any, that have been assigned to the subgraph;
detecting whether the subgraph including the newly assigned edges contains a common feature indicative of a trapping set or sets to be avoided during generation of the Tanner graph;
repeating the operations of assigning new edges to the subgraph and detecting whether the subgraph including the newly assigned edges contains the common feature until either the common feature is not detected or all possible combination of edges have been assigned to the subgraph;
including as part of the Tanner graph being generated the subgraph containing no occurrences of the common feature;
when the common feature is detected for all combinations of assigned edges, selecting one of combinations of edges as the subgraph and including the selected subgraph as part of the Tanner graph being generated; and
repeating the operations of generating a pseudo-random parameter through including the subgraph as part of the Tanner graph being generated until the entire Tanner graph is generated.

2. The method of claim 1, wherein the common feature comprises a two-edge connectivity of six-cycles.

3. The method of claim 1, wherein the method further comprises:
repeating N times the operations of claim 1 to generate N different Tanner graphs; and
selecting one of the N different Tanner graphs for use in decoding data encoded with the low density parity check code.

4. The method of claim 3, wherein selecting one of the N different Tanner graphs comprises selecting the Tanner graph having the fewest two-edge connectivity of six-cycles trapping sets.

5. The method of claim 1, wherein selecting one of combinations of edges as the subgraph and including the selected subgraph as part of the Tanner graph comprises selecting the combination of edges having the fewest occurrences of the common feature.

6. The method of claim 1, wherein the method further comprises:
detecting the presence of short cycles present in the subgraphs during generation of the Tanner graph; and
eliminating detected short cycles to the extent possible during generation of the Tanner graph.

7. The method of claim 6, wherein short cycles of length four are detected and eliminated.

8. A low density parity check decoder operable to decode data encoded with a low density parity check code, the decoder being adapted to receive blocks of soft information values and operable to provide an corresponding code word for each block of soft information values, the low density parity check decoder further comprising a Tanner graph that is utilized in decoding the blocks of soft information value and the Tanner graph and the Tanner graph containing a minimized number of occurrences of a two-edge connectivity of six-cycles common feature.

9. The low density parity check decoder of claim 8, further comprising a memory and wherein the Tanner graph is stored in the memory.

10. The low density parity check decoder of claim 9, wherein the memory comprises a FLASH memory.

11. A communications channel, comprising:
a storage medium;
write portion circuitry operable to receive message bits, encode the received message bits to generate encoded data, and store the encoded data on the storage medium;
read portion circuitry operable to read encoded data from the storage medium and to decode the encoded data to provide the message bits original input to the write portion circuitry, the read portion circuitry including,
analog equalization and timing circuitry operable to sense encoded data stored on the storage medium and provide signals indicative of the stored encoded data;
channel detection scheme circuitry operable to perform iterative decoding of the signals from the analog equalization and timing circuitry and to provide soft information values from this iterative decoding;
a low density parity check decoder coupled to receive soft information values from the channel detection scheme circuitry, the low density parity check decoder operable to decode data encoded with a low density parity check code, the decoder being adapted to receive blocks of soft information values and operable to provide a corresponding code word for each block of soft information values, the low density parity check decoder further comprising a Tanner graph that is utilized in decoding the blocks of soft information value and the Tanner graph and the Tanner graph containing a minimized number of occurrences of a two-edge connectivity of six-cycles common feature; and
RLL and CRC decode circuitry coupled to receive code words from the low density parity check decoder and operable to decode the received code words to provide the message bits originally input to the write portion circuitry.

12. The communications channel of claim 11, wherein the channel detection scheme circuitry performs iterative decoding of the signals from the analog equalization and timing circuitry using the soft output Viterbi algorithm (SOVA) or the BCJR algorithm.

13. The communications channel of claim 11,
wherein the analog equalization and timing circuitry is further operable to equalize analog signals corresponding to the sensed data from the storage medium to compensate for intersymbol interference, and
wherein the analog equalization and timing circuitry is further operable to perform analog-to-digital conversion of the equalized signals and to provide equalized samples that are digital signals.

14. The communications channel of claim 11, wherein the soft information values from the channel detection scheme circuitry are log-likelihood ratio values.

15. The communications channel of claim 11, wherein the Tanner graph of the low density parity check decoder is stored in a memory device.

16. The communications channel of claim 15, wherein the memory device comprises a ROM.

17. The communications channel of claim 11, wherein there is feedback between the channel detection scheme circuitry and the low density parity check decoder using turbo-equalization techniques.

18. An electronic system, comprising:
an input device;
an output device;
electronic circuitry coupled to the input and output devices; and
a storage device coupled to the electronic circuitry, the storage device including a storage medium and a communications channel operable to transfer encoded data between the storage medium and the electronic circuitry, the communications channel comprising,
write portion circuitry operable to receive message bits from the electronic circuitry, encode the received message bits to generate encoded data, and store the encoded data on the storage medium;
read portion circuitry operable to read encoded data from the storage medium and to decode the encoded data to provide the message bits original input to the write portion circuitry to the electronic circuitry, the read portion circuitry including,
analog equalization and timing circuitry operable to sense encoded data stored on the storage medium and provide signals indicative of the stored encoded data;
channel detection scheme circuitry operable to perform iterative decoding of the signals from the analog equalization and timing circuitry and to provide soft information values from this iterative decoding;
a low density parity check decoder coupled to receive soft information values from the channel detection scheme circuitry, the low density parity check decoder operable to decode data encoded with a low density parity check code, the decoder being adapted to receive blocks of soft information values and operable to provide a corresponding code word for each block of soft information values, the low density parity check decoder further comprising a Tanner graph that is utilized in decoding the blocks of soft information value and the Tanner graph and the Tanner graph containing a minimized number of occurrences of a two-edge connectivity of six-cycles common feature; and
RLL and CRC decode circuitry coupled to receive code words from the low density parity check decoder and operable to decode the received code words to provide the message bits originally input to the write portion circuitry.

19. The electronic system of claim 18, wherein the electronic circuitry comprises computer circuitry and wherein the storage device comprises a magnetic and/or optical disk.

20. The electronic system of claim 19, wherein the input device comprises at least one of a keyboard and a mouse.

21. The electronic system of claim 20, wherein the output device comprises at least one of a printer and video display.

22. The electronic system of claim 18, wherein the channel detection scheme circuitry performs iterative decoding of the signals from the analog equalization and timing circuitry using the soft output Viterbi algorithm (SOVA) or the BCJR algorithm.

23. The electronic system of claim 18,
wherein the analog equalization and timing circuitry is further operable to equalize analog signals corresponding to the sensed data from the storage medium to compensate for intersymbol interference, and
wherein the analog equalization and timing circuitry is further operable to perform analog-to-digital conversion of the equalized signals and to provide equalized samples that are digital signals.

24. The electronic system of claim 18, wherein the Tanner graph of the low density parity check decoder is stored in a memory device.

25. The electronic system of claim 24, wherein the wherein the memory device comprises at least one of a ROM and a FLASH memory.
